(19) United States
(12) Patent Application Publication
(10) Pub. No.: US 2007/0075786 A1
(43) Pub. Date: Apr. 5, 2007

(54) Suppressing noise in a frequency synthesizer

(76) Inventors: Adrian Maxim, Austin, TX (US); James Kao, Austin, TX (US)

Correspondence Address: TROP PRUNER & HU, PC, 1616 S. VOSS ROAD, SUITE 750, HOUSTON, TX, 77057-2631, US

(21) Appl. No.: 11/473,993

(22) Filed: Jun. 23, 2006

Related U.S. Application Data
(60) Provisional application No. 60/722,333, filed on Sep. 30, 2005.

(51) Int. Cl. H03L 7/00

(52) U.S. Cl. 331/16

(57) ABSTRACT

A frequency synthesizer includes analog components and digital components. The frequency synthesizer includes at least one shunt regulator that is coupled to a supply rail to provide power to at least one of the digital components. The frequency synthesizer also includes at least one series regulator that is coupled to the supply rail to provide power to at least one of the analog components.

This application claims the benefit under 35 U.S.C. §119(e) to U.S. Provisional Application No. 60/722,333, filed on Sep. 30, 2005, which is hereby incorporated by reference in its entirety.

### BACKGROUND

The invention generally relates to suppressing noise in a frequency synthesizer.

A phase locked loop (PLL)-based frequency synthesizer typically includes analog blocks (a loop filter and voltage controlled oscillator (VCO), as examples) that are sensitive to noise and digital blocks (a divider and a phase frequency detector, for example) that generate a significant amount of noise. Parasitic coupling and possibly supply rail coupling between the digital and analog blocks may significantly degrade the phase noise (i.e., the jitter) and spurious performance of the frequency synthesizer. The problem may be compounded when several PLL-based frequency synthesizers are integrated on the same die, share the same substrate and also share the same global voltage supply. Furthermore, a large and relatively noisy digital core may coexist with the on-chip frequency synthesizers.

Thus, there exists a continuing need for improved noise management for a frequency synthesizer.

### SUMMARY

In an embodiment of the invention, a frequency synthesizer includes analog components and digital components. The frequency synthesizer includes at least one shunt regulator that is coupled to a supply rail to provide power to at least one of the digital components. The frequency synthesizer also includes at least one series regulator that is coupled to the supply rail to provide power to at least one of the analog components.

In another embodiment of the invention, a wireless system includes a wireless interface and a frequency synthesizer. The frequency synthesizer includes a first charge pump and a second charge pump. The second charge pump operates in a complimentary fashion to the first charge pump to minimize current fluctuation occurring on a supply rail in response to the operation of the first charge pump.

Advantages and other features of the invention will become apparent from the following drawing, description and claims.

### BRIEF DESCRIPTION OF THE DRAWING

FIG. 1 is a block diagram of a PLL-based frequency synthesizer according to an embodiment of the invention.

FIG. 2 is a schematic diagram of a series regulator of the synthesizer of FIG. 1 according to an embodiment of the invention.

FIG. 3 is a schematic diagram of a charge pump according to an embodiment of the invention.

FIG. 4 is an illustration of a fabrication layout of certain components of the frequency synthesizer according to an embodiment of the invention.

FIG. 5 is a schematic diagram of an arrangement of charge pumps to stabilize a supply current according to an embodiment of the invention.

FIG. 6 is a schematic diagram depicting a shunt regulator for use with a frequency divider of the frequency synthesizer according to an embodiment of the invention.

FIG. 7 is a schematic diagram illustrating the use of current mode logic to stabilize a supply current according to an embodiment of the invention.

FIG. 8 is a schematic diagram illustrating power connections of a voltage controlled oscillator and an output buffer of the oscillator according to an embodiment of the invention.

FIG. 9 is a block diagram of a wireless device according to an embodiment of the invention.

FIGS. 10 and 11 are illustrations of architectures to provide power to phase locked loop blocks according to embodiments of the invention.

### DETAILED DESCRIPTION

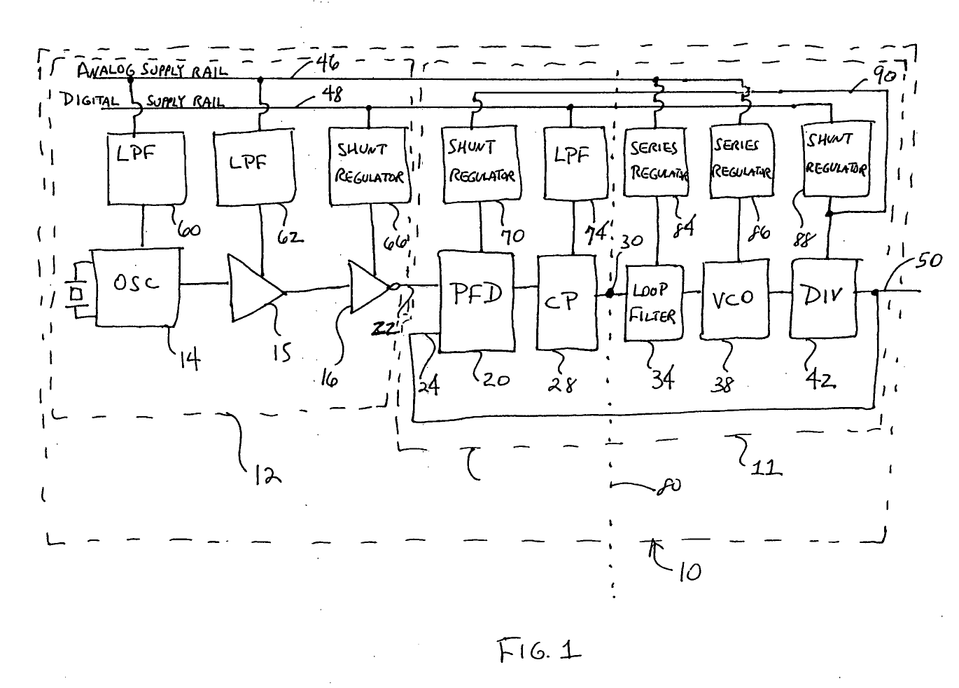

Referring to FIG. 1, a phase locked loop (PLL)-based frequency synthesizer 10 in accordance with an embodiment of the invention uses power supply partitioning for purposes of its decoupling noisy digital components from other analog components of the synthesizer 10. As described further below, the frequency synthesizer 10 uses a selective combination of shunt regulators, series regulators and low pass filters (LPFs) for purposes of suppressing the propagation of noise into the main signal radio frequency (RF) path of the frequency synthesizer 10.

Regarding the overall structure of the frequency synthesizer 10, the synthesizer 10 includes a reference clock generator 12 that generates a reference clock signal for a phase locked loop (PLL) 11. In response to the reference clock signal, the PLL 11 generates an output signal that has a predefined frequency and phase relationship to the reference clock signal. For example, in some embodiments of the invention, the PLL's output signal has the same phase as the reference clock signal and a frequency that is a multiple of the reference clock signal. The scaling of the output and reference clock frequencies may be used in applications where the frequency synthesizer is part of a radio tuner.

The PLL 11 includes a phase detector 20, a charge pump 28, a loop filter 34, a voltage controlled oscillator (VCO) 38 and a frequency divider 42. These components work together in the following manner. The phase detector 20 generates a signal that is indicative of a comparison between the PLL's output signal (appearing at an input terminal 24 of the phase detector 20 as a feedback signal) of the frequency synthesizer 10 and the reference clock signal. The signal that is provided by the phase detector 20, in turn, controls the charge pump 28 that produces a signal that passes through the loop filter 34. The loop filter 34 produces a control signal that controls the frequency of the VCO 38; and the resultant oscillating signal that is produced by the VCO 38 is scaled in frequency by the frequency divider 42 to produce the PLL's output signal at an output terminal 50 of the divider 42. When the frequency synthesizer 10 has achieved a lock, the output signal has a predetermined phase and frequency relationship to the reference clock signal.

In accordance with some embodiments of the invention, the reference clock generator 12 includes a reference oscillator, such as a crystal oscillator 14, which generates a sinusoidal signal. The sinusoidal signal passes through an isolation buffer 15 that drives a shaping, or squaring, circuit 15 that forms a resultant clock signal at a reference input terminal 22 of the phase detector 20. Therefore, the phase detector 20 of the PLL compares the reference clock signal that is present at the input terminal 22 with the feedback signal that is received at the input terminal 24 of the phase detector 20.

The above-described components of the frequency synthesizer 10 receive their power either from an analog supply rail 46 or a digital supply rail 48. Thus, the digital components of the frequency synthesizer 10, such as the squaring buffer 16, phase detector 20, charge pump 28 and frequency divider 42 receive their power from the digital supply rail 48; and the analog components of the frequency synthesizer, such as the oscillator 14, the buffer 15, the loop filter 34 and the VCO 38 receive their power from the analog supply rail 46.

It is noted that the dual supply rails 46 and 48 that are depicted in FIG. 1 may be replaced by a single supply rail, in accordance with other embodiments of the invention. Therefore, the systems and techniques that are disclosed herein may equally apply to single rail as well as dual rail systems, as many variations are possible and are within the scope of the appended claims.

As depicted in FIG. 1, for purposes of suppressing noise that may propagate to and/or from a particular analog or digital block of the frequency synthesizer 10, the synthesizer 10 has a separate power conditioning block for each component. For example, as depicted in FIG. 1, a low pass filter (LPF) 60 is coupled between the analog supply rail 46 and the power supply input terminal of the oscillator 14, an LPF 62 is coupled between the analog supply rail 46 and the power supply input terminal of the buffer 14; and an LPF 74 is coupled between the digital supply rail 48 and the power supply input terminal of the charge pump 28.

Series regulators condition power for other analog components of the frequency synthesizer 10: a series regulator 84 is coupled between the analog supply rail 46 and the power supply input terminal of the loop filter 34; and a series regulator 86 is coupled between the analog supply rail 46 and the power supply input terminal of the VCO 38.

Additionally, shunt regulators condition power for certain digital components of the frequency synthesizer 10: a shunt regulator 66 is coupled between the digital supply rail 48 and power supply input terminal of the squaring buffer 16; a shunt regulator 70 is coupled between the digital supply rail 48 and the phase detector 20; and a shunt regulator 88 is coupled between the digital supply rail 48 and the power supply input terminal of the frequency divider 42. As shown in FIG. 1, in accordance with some embodiments of the invention, the input terminal of the shunt regulator 70 may be coupled to the output terminal of the shunt regulator 88, in accordance with some embodiments of the invention.

The selection of which particular power conditioning block provides power to which analog/digital component depends on the particular function that is performed by the analog/digital component.

As a more specific example, the loop filter 34 is one of the most sensitive building blocks of the PLL 11 in terms of noise and supply-injected spurious tones. The loop filter 34 generates a control signal (i.e., a voltage or current) for the VCO 38. Therefore, the random noise that is present on the control signal degrades the synthesizer's sideband noise performance, while spurious tones on the control signal determine the spurious tones around the PLL's generated clock frequency.

The best choice for a loop filter from a supply noise and spur injection point of view is a passive filter. However, a passive architecture requires a large loop filter capacitance that often cannot be integrated on chip. An active filter helps reduce the size of the capacitance and therefore, allows the integration of the capacitance on chip. However, an active filter may require an additional power supply line that exposes the VCO control signal to supply noise and spur injection.

For purposes of preventing the communication of noise from the analog supply rail 46 to the loop filter 34, the series regulator 84 is used to power the loop filter 34. A series regulator provides a high forward power supply rejection ratio (PSRR), which means the series regulator 84 significantly attenuates any noise that is present on the analog supply rail 46 from propagating to the loop filter 34. A potential disadvantage of the series regulator 84 is that a significant voltage drop, called “head room,” may exist between the analog supply rail 46 and the power supply input terminal of the loop filter 34. However, as further described below, native transistor devices may be used to minimize, it not eliminate, the head room that is otherwise imposed by the series regulator 84.

The series regulator 86 provides power to VCO 38 for purposes of preventing noise from the analog supply rail 46 from propagating to the power supply input terminal of the VCO 38. As shown in FIG. 1, the series regulators 84 and 86 are located on one side of a partition 80 that is formed in the frequency synthesizer 10, which subdivides the analog components of the frequency synthesizer 10 about a high impedance output node 30 that is driven by the charge pump 28. Thus, on the left side of the partition 80, LPFs 60 and 62 are used to filter noise from the analog supply rail 46 for purposes of providing power to the oscillator 12 and the buffer 14, respectively; and on the right side of the partition 80, series regulators 84 and 86 power the loop filter 34 and VCO 38.

The shunt regulator 66, 70, 88 has both a large forward PSRR and a large reverse PSRR. The large reverse PSRR means that the shunt regulator significantly attenuates noise from propagating from the powered component back to the supply rail. In general, the shunt regulator is not well suited for large load currents. Thus, for larger load currents, the power that is dissipated by the shunt regulator disqualifies the shunt regulator for use in low power applications.

To summarize, for the analog components of the frequency synthesizer 10, which are upstream of the high impedance node 30 (to the left of the partition 80), LPFs are used to suppress noise from the analog supply rail 46. However, downstream of the high impedance node 30 (to the right side of the partition 80), series regulators 84 and 86 are used to provide power for the other analog components of the frequency synthesizer 10. For the relatively noisy digital switching components of the frequency synthesizer 10, shunt regulators are used to provide the power to these components. Additionally, in accordance with some embodiments of the invention, an LPF 74 is used to suppress noise that may be otherwise communicated from the digital supply rail 48 to the charge pump 28.

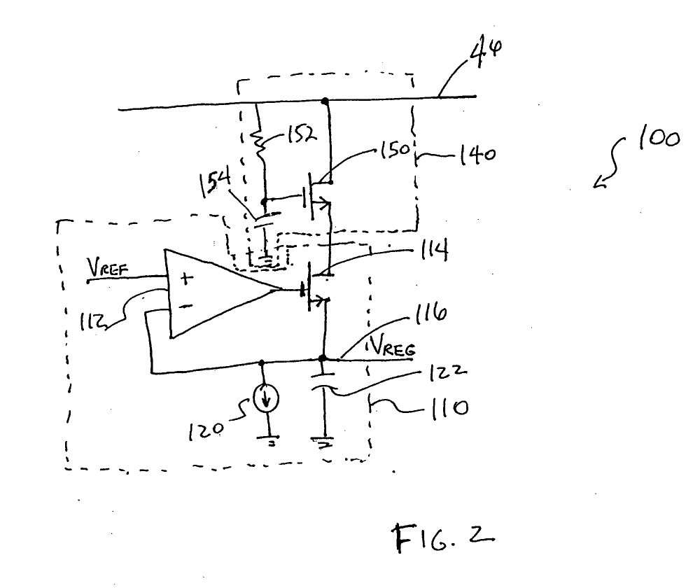

Referring to FIG. 2, in accordance with some embodiments of the invention, the series regulator 84, 86 may have an architecture 100. The architecture 100 includes an amplifier 112 that controls a pass transistor, such as an n-channel metal-oxide-semiconductor field effect transistor (NMOSFET) 114, for purposes of providing a regulated output voltage (called “V_{REG}” in FIG. 2) at an output terminal 116 in response to a supply voltage (called “V_{DD}” in FIG. 2) that is received on the analog supply rail 146. More specifically, the output terminal of the amplifier 112 provides a signal to the gate terminal of the NMOSFET 114 for purposes of regulating current conduction through the drain-to-source path of the NMOSFET 114. The amplifier 112 generates its output signal in response to a comparison between a reference voltage (called “V_{REF}” in FIG. 2) and the V_{REG} regulated output signal. Thus, in response to the V_{REG} output signal being above a regulated range, the amplifier 112 further turns off the NMOSFET 114 to lower the V_{REG} signal. Conversely, to raise the level of the V_{REG} output signal, the amplifier 112 further turns on the NMOSFET 114.

As depicted in FIG. 2, in accordance with some embodiments of the invention, an active RC filter 140 may be coupled between the analog supply rail 46 and the drain terminal of the NMOSFET 114. The active filter 140 further suppresses noise that may propagate from the supply rail 146. As depicted in FIG. 2, in accordance with some embodiments of the invention, the active filter 140 includes an NMOSFET 150. The drain terminal of the NMOSFET 150 is coupled to the supply rail 146, and the source terminal of the NMOSFET 150 is coupled to the drain terminal of the NMOSFET 114. The gate terminal of the NMOSFET 150 is coupled to one terminal of a capacitor 154 and one terminal of the a resistor 152. The other terminals of the resistor 152 and the capacitor 154 are coupled to the supply rail 146 and ground, respectively.

As also depicted in FIG. 2, the series regulator may include a bleed current source 120 that establishes a bias current through the drain-to-source paths of the NMOSFETs 114 and 150; and the series regulator 100 may also include a capacitor 122 that is coupled between the output terminal 116 and ground.

In accordance with some embodiments of the invention, the NMOSFETs 114 and 150 may be native (i.e., does not have threshold adjustment implantation) devices, which have zero or near zero threshold voltages. The condition for the active filter 140 to provide supply noise attenuation is that the NMOSFET 114 and 150 remain in saturation. This condition is guaranteed in that the effective threshold voltages for the NMOSFETs 114 and 150 are at least zero due to the bulk effect.

Alternatively, in accordance with some embodiments of the invention, the resistor 152 of the active filter 140 may be replaced by a current source; or alternatively, in other embodiments of the invention, a current source may be connected between the gate terminal of the NMOSFET 150 and ground.

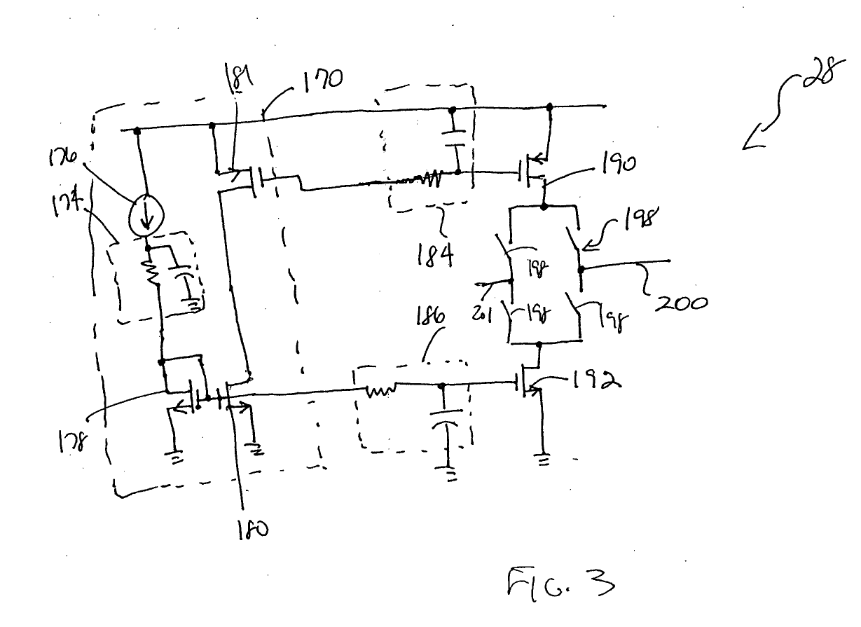

Referring to FIG. 3, in accordance with some embodiments of the invention, one or more LPFs may be incorporated into the charge pump 26. In the depicted embodiment, the charge pump 26 is a differential charge pump that includes switches 198 that are turned on and off at the reference frequency based on the phase difference between the reference and feedback clock signals. A resultant differential current is produced at differential output terminals 200 and 201, which create the control voltage that drives the VCO 38 (see FIG. 1).

Due to the switching action in the charge pump 28, the charge pump 28 is capable of causing a mixing effect between the reference frequency and any high frequency tone that is present in the charge pump 160. This mixing may downconvert high frequency spurious tones into the PLL bandwidth where the synthesizer 10 has little or no rejection capability. A low frequency spur once downconverted at low frequency and coupled into the charge pump 28 output controls the VCO 38 (see FIG. 1) and results in corresponding spurs around the output synthesized clock frequency.

There are two main mechanisms that may mix down high frequency spurs to the output of the charge pump 160. The first mechanism consists of high frequency tones that are present on the bias current of the charge pump 160. These tones may be directly subject to a mixing process achieved by the charge pump switches 198. To minimize the impact, a low comer frequency passive R-C filter 174 is coupled to a current mirror bias network 170 of the charge pump 160. One or more other filters may be used to subsequently filter the signal from the charge pump 160 at higher frequencies to obtain the desired roll-off characteristics.

As depicted in FIG. 3, the current bias network 170 may include, for example, a current source 176 that is coupled between a supply input terminal 170 (coupled to the output terminal of the LPF 74 (see FIG. 1)) and the LPF 174. NMOSFETs 178 and 180 that form a current mirror may be coupled to the LPF 174. In particular, the gate and drain terminals of the NMOSFET 178 may be coupled to the LPF 174, and the source terminals of the NMOSFET 178 may be coupled to ground. The mirroring NMOSFET 180 may have its gate terminal coupled to the gate terminal of the NMOSFET 178 so that the current in the drain-to-source path of the NMOSFET 180 is a scaled version of the current from the current source 176. A p-channel metal-oxide-semiconductor field effect transistor (PMOSFET) 181 has its source-to-drain path coupled in series with the drain-to-source path of the NMOSFET 180. The gate terminal of the PMOSFET 181 drives a PMOSFET 190 output transistor of the charge pump 160, and the gate terminal of the NMOSFET 180 provides a bias voltage to an NMOSET 192 that forms another output transistor of the charge pump 28.

Thus, as depicted in FIG. 3, the LPF 174 may be placed in series with the bias current from the current source 176 to ensure additional filtering for the high frequency noise and high frequency spurious tones. To minimize the noise impact of the thermal noise that is generated by the filtering resistors, a relatively large filtering capacitor may be used.

As also depicted in FIG. 3, LPFs 184 and 186 are coupled between to gate terminals of the PMOSFET 190 and NMOSFET 192, respectively, to further filter the bias voltages. The LPFs 184 and 186 also help rejecting intrinsic noise of the input devices 180 and 181, minimizing their impact on the charge pump output noise current.

The second mechanism that may mix down high frequency spurs at the output of the charge pump 28 is random noise and spurs that are present at the supply input terminal 170 of the charge pump 160. To combat this noise, the amount of high frequency spurious tones that are present are minimized using the techniques that are described herein.

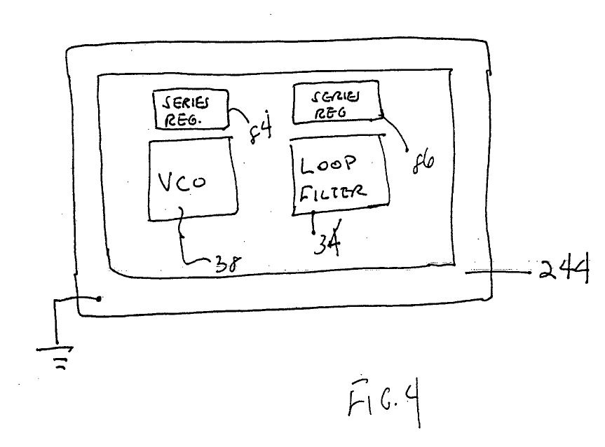

In most processes, the native devices may be realized only directly in the global substrate of the die and thus, cannot be placed in an isolated well. Therefore, there may be a parasitic noise coupling from the global substrate to the source of a particular native device via the gmb transconductance. Therefore, referring to FIG. 4, in accordance with some embodiments of the invention, n-well guard rings are used to prevent the noise coupling. As depicted in FIG. 4, an n-well guard ring 244 may be located around certain components of the frequency synthesizer 10, which contain native devices. For example, in accordance with some embodiments of the invention, the VCO 38, the series regulator 84, the series regulator 86 and the loop filter 34 may be all located inside the n-well guard ring 244. In addition, a deep n-well guard ring placed underneath the n-well ring increases the height of the noise barrier, thereby further reducing the coupled noise. Furthermore, a low doped native ring helps further reducing the noise coupling to the sensitive blocks.

Additionally, in accordance with some embodiments of the invention, a deep n-well may be used to protect field effect devices from coupled noise.

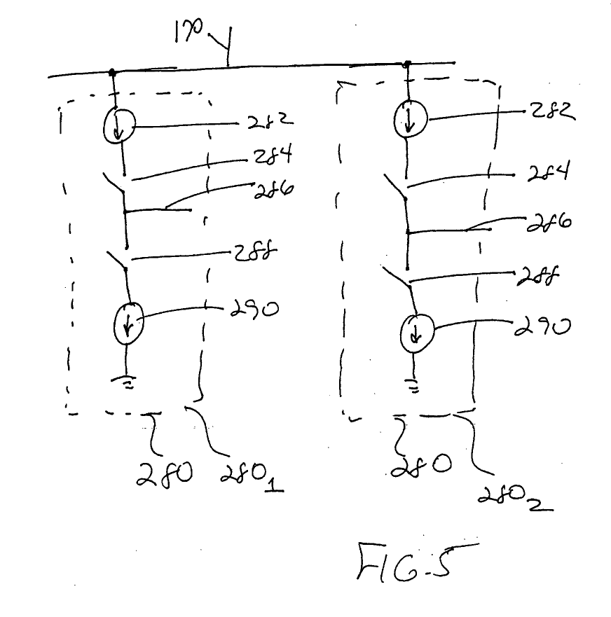

Referring to FIG. 5, in accordance with some embodiments of the invention, the charge pump 28 may be single-ended instead of being differential-based. In this regard, FIG. 5 depicts two charge pumps 280₁ and 280₂ that generally share a common architecture 280. The architecture 280 includes a single-ended charge pump 280 that has two current sources 282 and 291. A switch 284 is located between the current source 282 and an output terminal 286; and a switch 288 is coupled between the output terminal 286 and the current source 290.

The single-ended charge pump presents a challenge in that operation of the charge pump produces supply current impulses that may propagate to the digital supply rail 48 (see FIG. 1). It is noted that both current sources 290 and 282 are coupled to the power supply input terminal 170, as only the relevant current paths of the sources 290 and 282 are depicted in FIG. 5. Therefore, in accordance with some embodiments of the invention, the single-ended charge pump 280₂ is operated to produce the control signal for the loop filter 34; and the other single-ended charge pump 280₂ is operated as a “dummy” charge pump in a complimentary fashion relative to the charge pump 280₁ for purposes of minimizing the current impulse otherwise produced on the supply rail 251. Therefore, for example, when the charge pump 280₁ is operated to raise the voltage on its output terminal, the charge pump 280₂ is operated in a complimentary fashion. This complimentary action substantially cancels any impulse that otherwise occurs in the supply current. Thus, from a supply perspective, the collective current drawn by the charge pumps 280₁ and 280₂ remains constant.

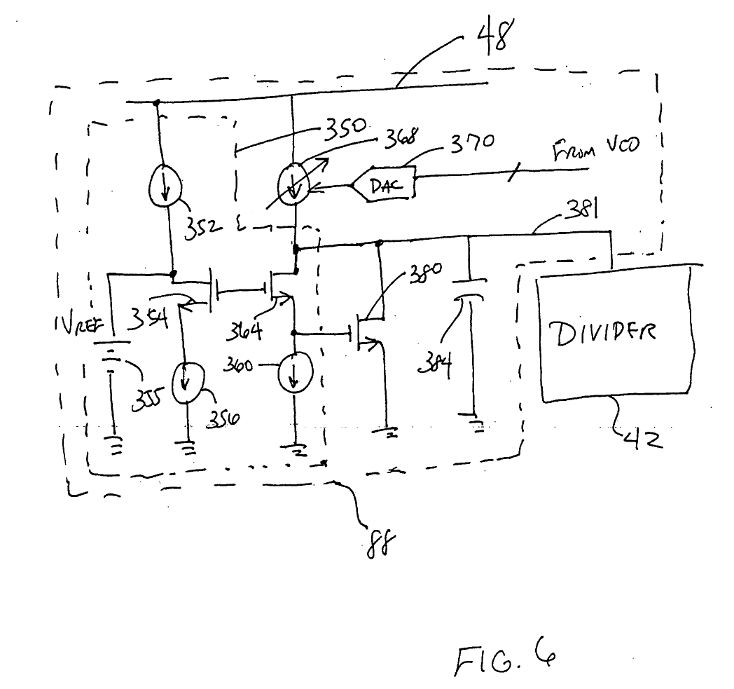

FIG. 6 depicts an embodiment of the shunt regulator 88 (see FIG. 1) in accordance with some embodiments of the invention. The shunt regulator 88 is depicted as providing power to a supply input terminal 381 of a frequency divider 42. The frequency divider 42 is an example of a digital circuit whose power consumption is dependent upon the process corners. In this regard, for a relatively slower process, the frequency divider 42 draws a higher current from the shunt regulator 88; and for a relatively faster process, the frequency divider 42 draws a lower current from the shunt regulator 88.

The shunt regulator 88 includes a current source 368 that is sized to provide more current than the maximum current that is demanded by the frequency divider 42. If the current source 368 were sized to for the slowest process (i.e., the highest possible current draw from the frequency divider 42), then power would be wasted for a faster process. Therefore, in accordance with some embodiments of the invention, the current source 368 has a current level that is regulated in response to the process corners.

More specifically, in accordance with some embodiments of the invention, a digital-to-analog converter (DAC) 370 of the shunt regulator 88 receives a digital indication of the process and provides a corresponding analog signal to control the level of current that is provided by the current source 368. In some embodiments of the invention, the DAC 370 may receive a digital indication of a bias current of the VCO 38, which may serve as a process indication. Thus, a higher VCO bias current may indicate a slower process and cause the DAC 370 to provide a digital signal that causes the current source 368 to provide a relatively higher output current; and conversely, a lower VCO bias current may indicate a faster process and cause the DAC 370 to provide a digital signal that causes the current source 368 to provide a relatively lower output current.

The shunt regulator 88 includes a shunt device, such as an NMOSFET 380, for purposes of regulating a current from the supply input terminal 381 of the frequency divider 42 to regulate a supply voltage of the shunt regulator output terminal 381. As shown in FIG. 6, the drain-to-source path of the NMOSFET 380 is coupled between the supply input terminal 381 and ground. Therefore, for purposes of lowering the voltage on the supply input terminal 381 the NMOSFET 380 conducts more current; and conversely, to raise the voltage of the input supply terminal 381, the NMOSFET 380 conducts less current. As depicted in FIG. 6, a filtering capacitor 384 may be coupled between the output terminal 381 and ground.

The voltage of the output terminal 381 is regulated via a reference voltage (called “V_{REF}” in FIG. 6) that is part of a bias circuit 350. The bias circuit 350 includes a current source 352 that is coupled between the digital supply rail 48 and a drain terminal of an NMOSFET 354. The drain terminal of the NMOSFET 354 also receives the V_{REF} reference voltage. The source terminal of the NMOSFET 354 is coupled to one terminal of a current source 356, and the other terminal of the current source 356 is coupled to ground. The current sources 352 and 356 provide the current that flows through the drain-to-source path of the NMOSFET 354. A current source 360 is coupled between the source terminal of an NMOSFET 364 and ground, and the gate terminals of the NMOSFET 354 and 364 are coupled together. The drain terminal of the NMOSFET 364 is coupled to the input supply terminal 381 and also to the current source 368.

Another way to minimize the impulsive supply current of the divider 42 is to use differential current mode logic (CML) instead of standard single-ended complimentary metal oxide semiconductor (CMOS) logic. The advantage of the CML logic is pseudo-constant supply current and the faster speed to the reduced voltage and lower impedance at the signal nodes. The disadvantages are the larger DC power consumption required by the CML logic.

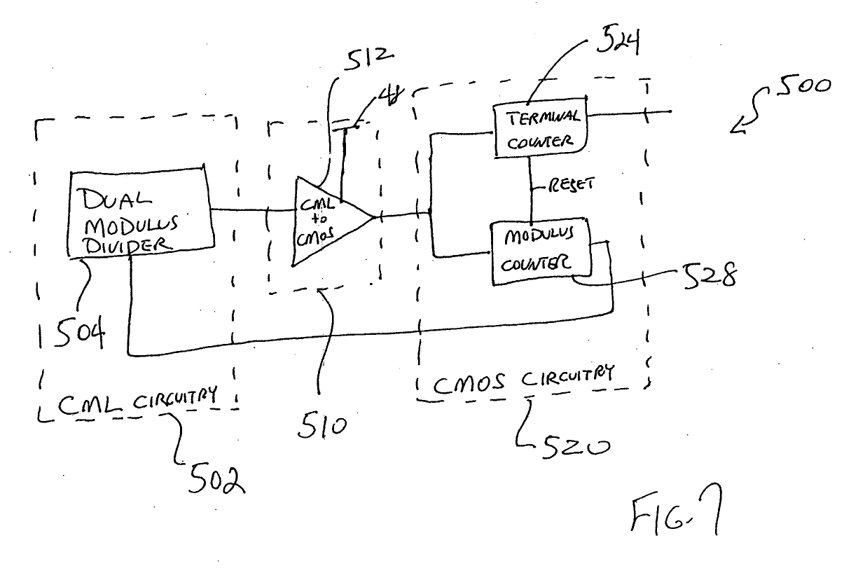

Therefore, referring to FIG. 7, a hybrid frequency divider architecture 500 may be used in some embodiments of the invention. Pursuant to the hybrid architecture 500, CML circuitry 502 is used at the front end of the divider for speed purposes, while the back end 520 of the divider is realized in standard CMOS for power savings. A CML to CMOS stage 510 (containing a CML to CMOS converter 512) is placed between the front end 502 and the back end 520 of the divider 500. This block is the most sensitive block in terms of supply noise rejection.

As a more specific example, the front end 502 may include a dual modulus divider 500; and back end 520 may include a modulus counter 528 that is coupled to a terminal counter 524 of the divider 500.

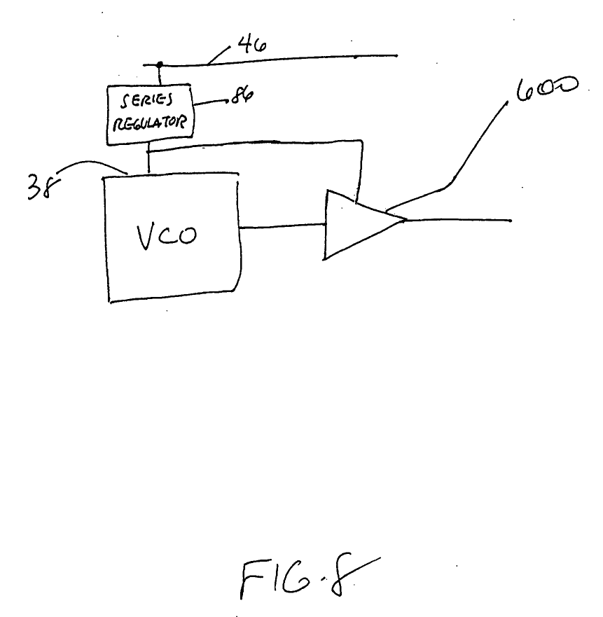

Referring to FIG. 8, in accordance with some embodiment of the invention, an output buffer 600 for the VCO 38 may be coupled to receive the same supply voltage from the series regulator 86. Thus, the output buffer 600 and the VCO 38 are coupled to the same supply. The large current spikes that are produced by the output buffer 600 are perfectly synchronous with the clock signal that is generated by the VCO 38, and therefore, these current spikes do not affect the phase noise or spurious performance of the VCO 38.

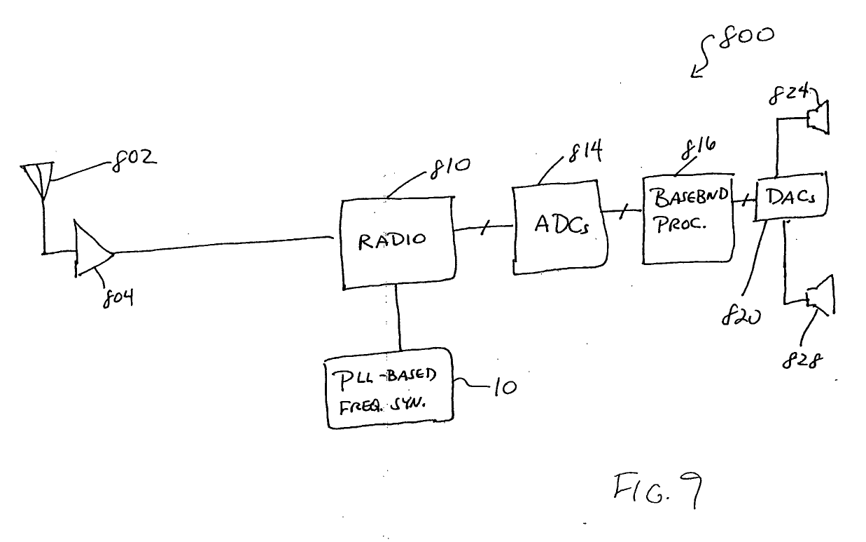

Referring to FIG. 9, in accordance with some embodiments of the invention, the frequency synthesizer 10 may be part of a wireless system 800. As examples, the wireless system 800 may be a portable wireless device, such as a cellular telephone, a personal digital assistant (PDA), or a portable computer, as just a few examples. It is noted that the wireless system 800 may be a more non-portable device, such as a desktop computer, in other embodiments of the invention. Thus, many variations are possible and are within the scope of the appended claims.

The wireless system 800 includes, for example, a transceiver that may include a low noise amplifier (LNA) 804 that receives an RF signal from an antenna 802, a radio 810, analog-to-digital converters (ADCs) 814, a baseband processor 816 and digital-to-analog converters (DACs) 820, and the frequency synthesizer 10. All of these components may be fabricated on a single die and may be part of the same semiconductor package, in accordance with some embodiments of the invention. In other embodiments of the invention, the above-described components may be fabricated on separate dies of a single semiconductor package. In yet other embodiments of the invention, the above-describe components may be part of separate semiconductor packages. Thus, many variations are possible and are within the scope of the appended claims.

The LNA 804 receives an RF signal from an antenna 802 and provides an amplified version of the incoming RF signal to a radio 810. The radio 810 receives one or more mixing signals from the frequency synthesizer 10 for purposes of translating the incoming RF signal to a lower baseband frequency. The resultant signal is provided to the ADCs 814 that produce baseband signals in response thereto. The baseband processor 816 may, for example, de-modulate the signals provided by the ADC 814 and provide the resultant de-modulated signals to the DACs 820. The DACs 820, in turn, may provide audio signals for speakers 824 and 828.

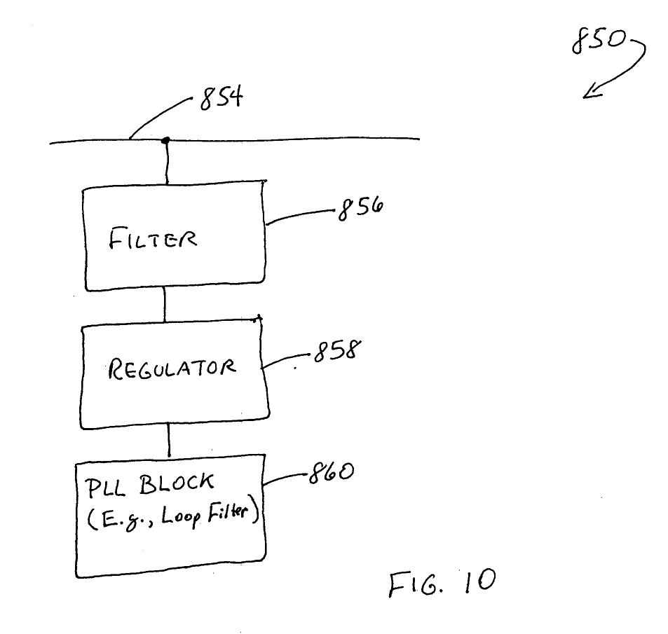

Referring to FIG. 10, in accordance with some embodiments of the invention, an architecture 850 may be used to supply power to a PLL block 860, such as a loop filter (for example). The PLL block 860 may require both a high PSRR and a supply voltage that is near the supply voltage that is present on a supply line 854. A single regulator, such as a regulator 858 that is depicted in FIG. 10, may not consume much headroom but may not by itself provide a sufficient PSRR. Although another regulator may be cascaded to the regulator 858 to increase the overall PSRR, the addition of the second regulator may consume too much headroom so that the supply voltage that is furnished to the PLL block 860 is too low.

For purposes of achieving the high PSRR and a low headroom, the architecture includes a filter 856 (an active filter that uses native devices, for example) to increase the PSRR. As depicted in FIG. 10, the filter 856 may be coupled between the supply line 854 and the regulator 858; and the regulator 858 may be coupled to the PLL block 860.

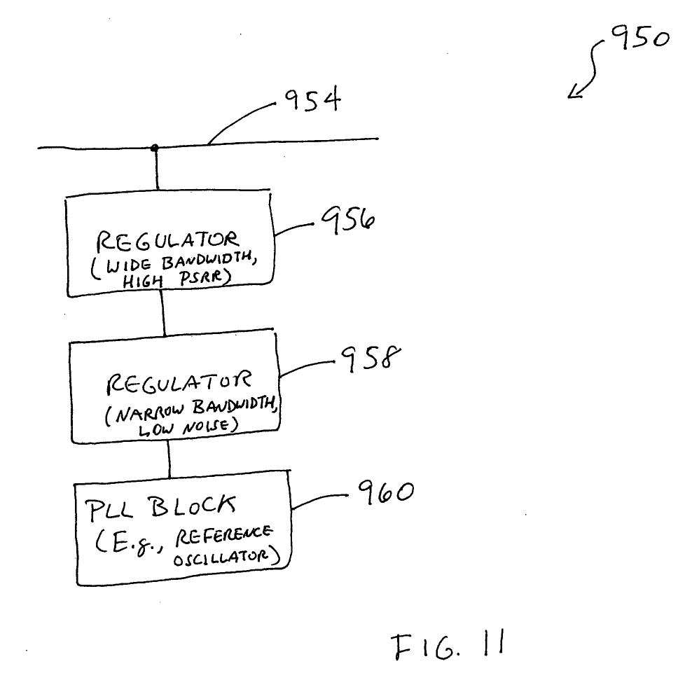

Referring to FIG. 11, in accordance with some embodiments of the invention, an architecture 950 may be used to supply power to a PLL block 960, such as a reference oscillator (for example). The PLL block 960 may require both a high PSRR and a low output noise from its supply voltage source. However, it may be difficult to achieve these characteristics from a single regulator because a regulator that has a high PSRR typically produces an output voltage that has a relatively large amount of noise.

To overcome these limitations, in accordance with some embodiments of the invention, the architecture 950 uses two cascaded regulators: a regulator 956 that has a relatively wide bandwidth and high PSRR; and a regulator 958 that has a relatively narrow bandwidth and a low output noise. As depicted in FIG. 11, the regulator 956 may be coupled to the supply line 954, and the regulator 958 may be coupled between the regulator 956 and the PLL block 960. As a result of the architecture 950, a high PSRR and low noise supply source provides power to the PLL block 960.

While the present invention has been described with respect to a limited number of embodiments, those skilled in the art, having the benefit of this disclosure, will appreciate numerous modifications and variations therefrom. It is intended that the appended claims cover all such modifications and variations as fall within the true spirit and scope of this present invention.

What is claimed is:

1. A frequency synthesizer comprising:
analog components;
digital components;
at least one shunt regulator coupled to a supply rail to provide power to at least one of the digital components; and
at least one series regulator coupled to a supply rail to provide power to at least one of the analog components.

2. The frequency synthesizer of claim 1, wherein said at least one digital component comprises a frequency divider.

3. The frequency synthesizer of claim 1, wherein said at least one digital component comprises a phase detector.

4. The frequency synthesizer of claim 1, wherein at least one of the analog components comprises a voltage controlled oscillator.

5. The frequency synthesizer of claim 1, wherein at least one of the analog components comprises a reference oscillator.

6. The frequency synthesizer of claim 1, wherein at least one of the analog components comprises a shaping circuit.

7. The frequency synthesizer of claim 1, wherein the analog components comprise a reference oscillator, a shaping circuit and a voltage controlled oscillator;
the digital components comprise a phase detector and a frequency divider; and
each of the reference oscillator, the shaping circuit and the voltage controlled oscillator receives power from a different one of the shunt regulators; and
each of the phase detector and the frequency divider receives power from a different one of the series regulators.

8. The frequency synthesizer of claim 1, further comprising:
an active filter coupled to at least one of said at least one shunt regulators.

9. The frequency synthesizer of claim 1, wherein at least one of said at least one shunt regulator comprises a native transistor.

10. The frequency synthesizer of claim 1, wherein at least one of said at least one series regulator comprises a native transistor.

11. A frequency synthesizer comprising:
a first charge pump coupled to a supply rail; and
a second charge pump coupled to the supply rail to operate in a complimentary fashion relative to the first charge pump to minimize current fluctuations on the supply rail due to the operation of the first charge pump.

12. The frequency synthesizer of claim 11, wherein the first charge pump and the second charge pump comprise single-ended charge pumps.

13. A wireless system comprising:
a wireless interface; and
a frequency synthesizer comprising:
analog components;
digital components;
at least one shunt regulator coupled to a supply rail to provide power to at least one of the digital components; and
at least one series regulator coupled to a supply rail to provide power to at least one of the analog components.

14. The wireless system of claim 13, wherein the analog components comprise a reference oscillator, a shaping circuit and a voltage controlled oscillator;
the digital components comprise a phase detector and a frequency divider; and
each of the reference oscillator, the shaping circuit and the voltage controlled oscillator receives power from a different one of the shunt regulators; and
each of the phase detector and the frequency divider receives power from a different one of the series regulators.

15. The wireless system of claim 13, further comprising:
an active filter coupled to at least one of said at least one shunt regulators.

16. The wireless system of claim 13, wherein at least one of said at least one shunt regulator comprises a native transistor.

17. The wireless system of claim 13, wherein at least one of said at least one series regulator comprises a native transistor.

18. A wireless system comprising:
a wireless interface; and
a frequency synthesizer comprising:
a first charge pump coupled to a supply rail; and
a second charge pump coupled to the supply rail to operate in a complimentary fashion relative to the first charge pump to minimize current fluctuations on the supply rail due to the operation of the first charge pump.

19. The wireless system of claim 18, wherein the first charge pump and the second charge pump comprise single-ended charge pumps.

20. A method comprising:
providing a frequency synthesizer that includes analog components and digital components;
providing at least one shunt regulator to provide power to at least one of the digital components; and
providing at least one series regulator to provide power to at least one of the digital components.

21. The method of claim 20, wherein said at least one digital component comprises a frequency divider.

22. The method of claim 20, wherein said at least one digital component comprises a phase detector.

23. The method of claim 20, wherein at least one of the analog components comprises a voltage controlled oscillator.

24. The method of claim 20, wherein at least one of the analog components comprises a reference oscillator.

25. The method of claim 20, wherein at least one of the analog components comprises a shaping circuit.

26. The method of claim 20, wherein the analog components comprise a reference oscillator, a shaping circuit and a voltage controlled oscillator;
the digital components comprise a phase detector and a frequency divider; and
each of the reference oscillator, the shaping circuit and the voltage controlled oscillator receives power from a different one of the shunt regulators; and
each of the phase detector and the frequency divider receives power from a different one of the series regulators.

27. The method of claim 20, further comprising:
an active filter coupled to at least one of said at least one shunt regulators.

28. The method of claim 20, wherein at least one of said at least one shunt regulator comprises a native transistor.

29. The method of claim 20, wherein at least one of said at least one series regulator comprises a native transistor.
